(19) United States
(12) Patent Application Publication
(10) Pub. No.: US 2016/0148966 A1
(43) Pub. Date: May 26, 2016

(54) Space-Efficient PCB-Mountable Image Sensor, And Method For Fabricating Same

(71) Applicant: OmniVision Technologies, Inc., Santa Clara, CA (US)

(72) Inventors: Wei-Feng Lin, Hsinchu City (TW); Chi-Chih Huang, Hsinchu City (TW)

(21) Appl. No.: 14/554,970

(22) Filed: Nov. 26, 2014

(51) Int. Cl. H01L 27/146

(52) U.S. Cl. CPC H01L 27/14636; H01L 27/14687

(57) ABSTRACT

A space-efficient PCB-mountable image sensor includes a semiconductor substrate having a top surface and a side surface, a bond pad on the top surface, and a conductive layer formed on the side surface and electrically connected to the bond pad. A camera module includes a PCB and a space-efficient PCB-mountable image sensor. A conductive layer of the PCB-mountable image sensor is electrically connected between the bond pad and a contact pad of the PCB. A method for fabricating a space-efficient PCB-mountable image sensor includes forming a trench next to an image sensor on a first side of an image sensor wafer, the image sensor including a bond pad. The method also includes forming a conductive layer spanning the bond pad and at least part of a side wall of the trench, and singulating the image sensor wafer along the trench.

### BACKGROUND

The present invention relates to image sensors and electrically connecting image sensors to a printed circuit board.

Camera modules in products such as stand-alone digital cameras, mobile devices, automotive components, and medical devices often include a complementary metal-oxide-semiconductor (CMOS) image sensor. The CMOS image sensor converts light imaged by a camera lens into a digital signal that is converted into a displayed image and/or file containing the image data. The image sensor is typically surface-mounted onto a printed circuit board (PCB).

FIG. 1 is a plan view of a prior-art CMOS image sensor 100 with a plurality of bond pads 121 that are electrically connected to a respective contact pad 132 of a PCB 102 with a respective wire bond 134. Bond pads 121 are on a semiconductor substrate 107. The above-mentioned products include a camera module PCB similar to PCB 102. For clarity of illustration, not all contact pads 132 and wire bonds 134 in FIG. 1 are labeled. FIG. 2 is a cross-sectional view of camera module PCB 102 along cross-section 2-2′. Wire bonds 134 have a minimum radius of curvature to prevent breaking, which requires contact pads 132 to be at a minimum distance 142 from image sensor 100, which impedes efficient use of PCB area. The minimum radius of curvature also results in wire bonds 134 having a height 149 above semiconductor substrate 107.

### SUMMARY OF THE INVENTION

In an embodiment, a space-efficient PCB-mountable image sensor includes a semiconductor substrate having a top surface and a side surface, a bond pad on the top surface, and a conductive layer formed on the side surface and electrically connected to the bond pad.

In an embodiment, a method for fabricating a space-efficient PCB-mountable image sensor includes forming a trench next to an image sensor on a first side of an image sensor wafer. The image sensor includes a pixel array and a bond pad between the trench and the pixel array. The method also includes forming a conductive layer spanning the bond pad and at least part of a side wall of the trench; and singulating the image sensor wafer along the trench.

In an embodiment, a camera module includes a PCB including a contact pad and an image sensor disposed on the PCB. The image sensor includes a semiconductor substrate having a top surface and a side surface, a bond pad on the top surface, and a conductive layer formed on the side surface and electrically connected between the bond pad and the contact pad.

### BRIEF DESCRIPTION OF THE FIGURES

FIG. 1 is a plan view of a prior-art image sensor electrically connected to a PCB with wire bonds.

FIG. 2 is a cross-sectional view of the camera module PCB of FIG. 1.

FIG. 3 is a plan view of a space-efficient PCB-mountable image sensor, in an embodiment.

FIG. 4 is a cross-sectional view of the space-efficient PCB-mountable image sensor of FIG. 3.

FIG. 5 is a perspective view of an image sensor wafer that includes a plurality of CMOS image sensors, in an embodiment.

FIG. 6 is a flowchart illustrating an exemplary wafer-level method for fabricating a space-efficient PCB-mountable image sensor, in an embodiment.

FIG. 7 is a cross-sectional view of the image sensor wafer of FIG. 5.

FIG. 8 is a cross-sectional view of the image sensor wafer with an isolation layer thereon, in an embodiment.

FIG. 9 is a cross-sectional view of the image sensor wafer of FIG. 8 with a redistribution layer and a reflowable conductive element, in an embodiment.

FIG. 10 is a cross-sectional view of a pre-cut image sensor wafer, in an embodiment.

FIG. 11 is a perspective view of the pre-cut image sensor wafer of FIG. 10.

FIG. 12 is a cross-sectional view showing two space-efficient PCB-mountable image sensors singulated from the pre-cut image sensor wafer of FIG. 11, in an embodiment.

FIG. 13 shows the space-efficient PCB-mountable image sensor of FIG. 12 die-bonded to a module PCB, in an embodiment.

FIG. 14 shows a camera module that includes the space-efficient PCB-mountable image sensor of FIG. 12 electrically connected to the module PCB of FIG. 13, in an embodiment.

### DETAILED DESCRIPTION

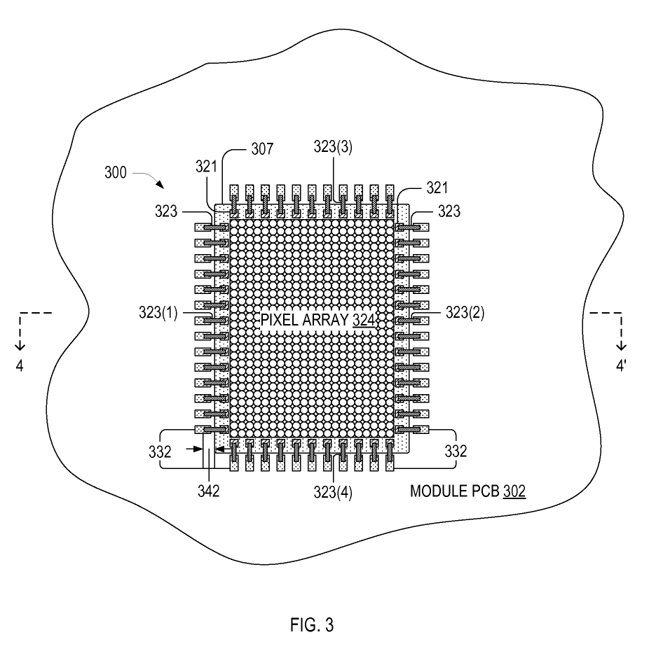

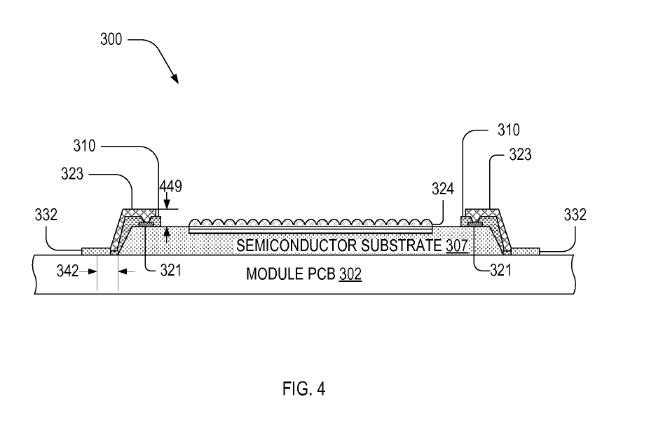

FIG. 3 is a plan view of a space-efficient PCB-mountable image sensor 300. FIG. 4 is a cross-sectional view of space-efficient PCB-mountable image sensor 300 along cross-section 4-4′. FIGS. 3 and 4 are best viewed together in the following description.

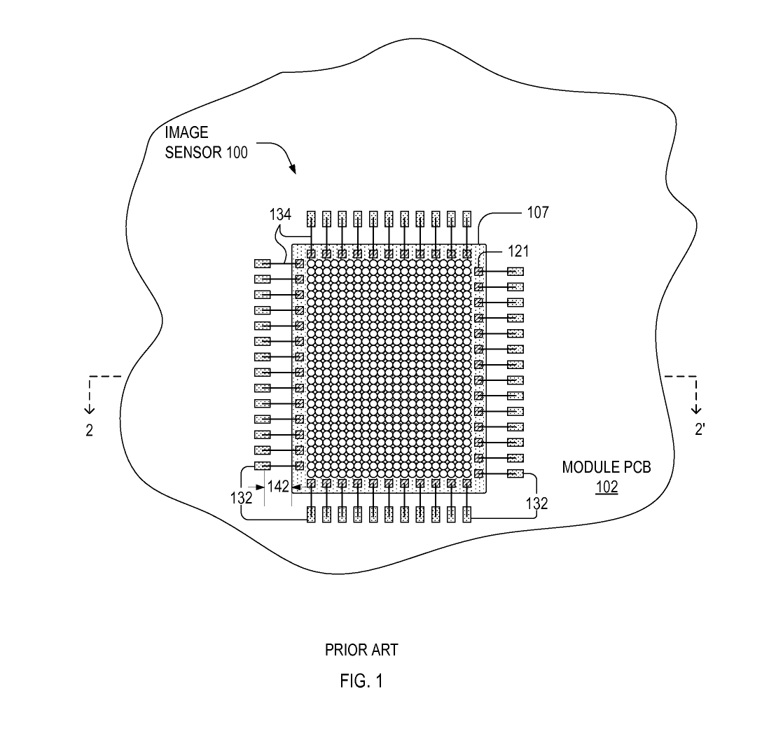

Space-efficient PCB-mountable image sensor 300 includes a semiconductor substrate 307, a pixel array 324, a plurality of bond pads 321, and a plurality of sensor-edge conductors 323. Semiconductor substrate 307 is formed of silicon, for example. Each bond pad 321 is electrically connected to a respective sensor-edge conductor 323, which is formed of a redistribution layer (RDL), for example. An isolation layer 310 is beneath each sensor-edge conductor 323, as shown in FIG. 4. Isolation layer 310 may be an oxide such as silicon dioxide, and may be formed by a spin process, a spray process, other thin-film deposition methods, and layer patterning methods including photolithographic masking and others. Each sensor-edge conductor 323 electrically connects a respective bond pad 321 to a contact pad 332 of a module PCB 302. Contact pad 332 and module PCB 302 are similar to contact pads 132 and PCB 102 of FIG. 1, respectively.

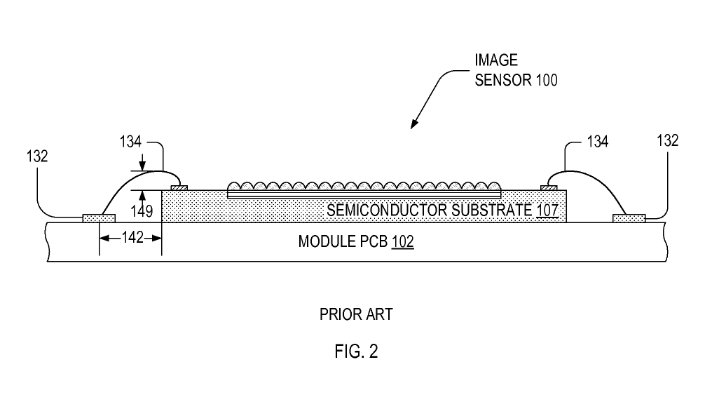

A minimum distance 342 between each contact pad 332 and space-efficient PCB-mountable image sensor 300 is less than minimum distance 142 of prior-art image sensor 100. Sensor-edge conductor 323 has a height 449 above semiconductor substrate 307 that is less than height 149 of wire bonds 134 above semiconductor substrate 107, FIG. 2. In an embodiment of space-efficient PCB-mountable image sensor 300, isolation layer 310 and sensor-edge conductor 323 each have a thickness between 1 μm and 2 μm. For clarity of illustration, in FIG. 3, the thickness of sensor-edge conductor 323 and isolation layer 310 are enlarged, and not all bond pads 321, sensor-edge conductors 323, and contact pads 332 are labeled.

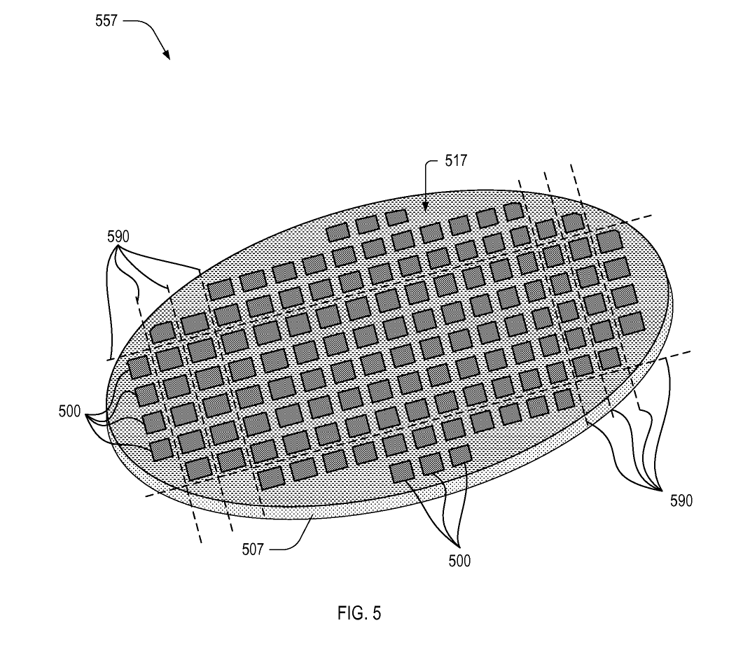

FIG. 5 is a perspective view of an image sensor wafer 557 that includes plurality CMOS image sensors 500 and a semiconductor substrate 507. Each CMOS image sensor 500 includes a pixel array having adjacent bond pads, not shown, that are similar to pixel array 324 and bond pads 321, FIG. 3. FIG. 5 includes a plurality of scribe lines 590 between adjacent rows and columns of CMOS image sensors 500 that denote where CMOS image sensors 500 are singulated. Image sensor wafer 557 has a top surface 517. Scribe lines 590 are for illustrative purposes only and are not physically part of image sensor wafer 557. Semiconductor substrate 507 is formed of silicon, for example.

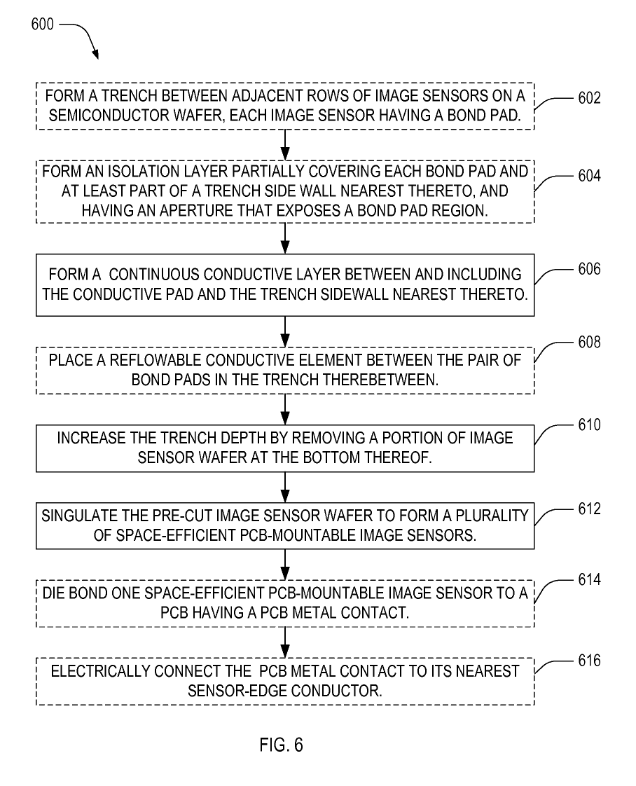

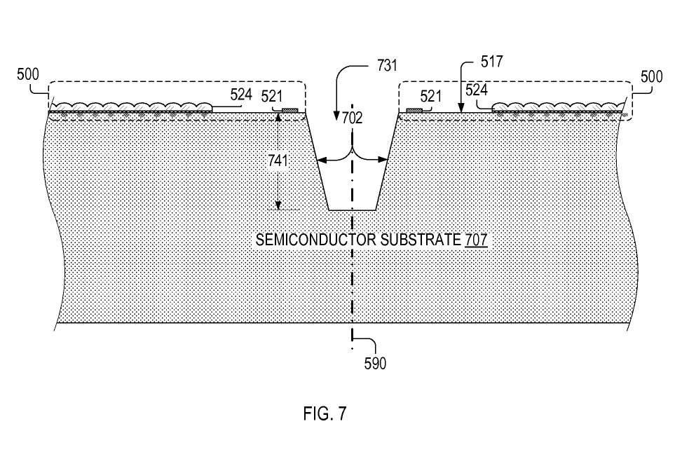

FIG. 6 is a flowchart illustrating an exemplary wafer-level method 600 for fabricating a space-efficient PCB-mountable image sensor. FIGS. 7-14 illustratively represent the results of steps included in one example of method 600. FIG. 6 and FIGS. 7-14 are best viewed together with the following description. Method 600 may form either a single space-efficient PCB-mountable image sensor or a plurality of space-efficient PCB-mountable image sensors.

In step 602, method 600 forms a trench between adjacent rows of image sensors on a semiconductor wafer. Each image sensor includes a pixel array and bond pads communicatively coupled thereto. The bond pads are between the pixel array and the trench.

FIG. 7 is a cross-sectional view of image sensor wafer 557 through a plane perpendicular to top surface 517, which includes two CMOS image sensors 500 with a scribe line 590 therebetween. Each CMOS image sensor 500 includes a pixel array 524 and a bond pad 521. In an example of step 602, a scribe-line trench 731 is formed in semiconductor substrate 507 between CMOS image sensors 500, resulting in a semiconductor substrate 707. Trench 731 has a trench depth 741 and includes side-wall surfaces 702. Trench 731 may be trapezoidal, as shown in FIG. 7, or have vertical sidewalls, or multi-stepped sidewalls without departing from the scope hereof.

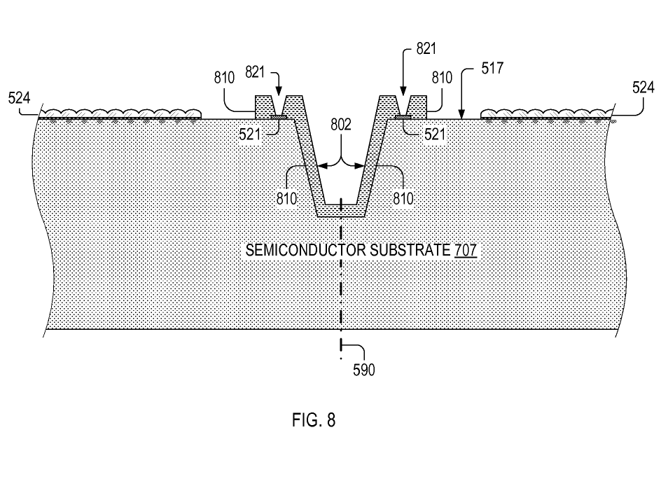

Step 604 is optional. If included, in step 604, method 600 forms an isolation layer partially covering each bond pad and at least part of a trench side wall nearest thereto, and having an aperture that exposes a bond pad region. In an example of step 604, an isolation layer 810 is formed on semiconductor substrate 707, as shown in FIG. 8. Isolation layer 810 is similar to isolation layer 310, and includes openings 821 that expose a respective bond pad 521. Isolation layer 810 includes side-wall surfaces 802.

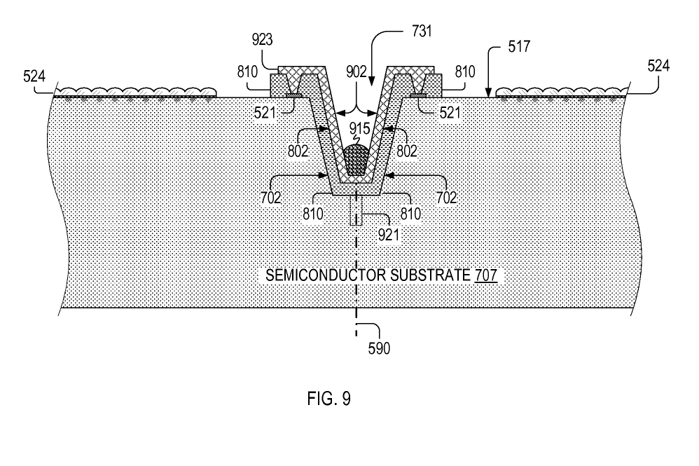

In step 606, method 600 forms a continuous conductive layer between and including each bond pad and the trench sidewall nearest thereto. In an example of step 606, an RDL 923 is formed on bond pads 521 and side-wall surfaces 802 of isolation layer 810, as shown in FIG. 9. In an embodiment of method 600 that does not include the isolation layer applied in step 604, step 606 forms a conductive layer on bond pads 521 and side-wall surfaces 702 of trench 731.

RDL 923 may be formed by electromechanical plating and patterned with a photoresist. RDL 923 may be formed of one or more of Al, an Al-Cu alloy, and Cu, and may have a metal finish formed of a nickel layer and a gold layer, as known in the art. Scribe-line trench 731 includes sidewall surfaces 902 of RDL 923. Without departing from the scope hereof, RDL 923 may have a gap at the bottom of scribe-line trench 731 such that RDL 923 does not electrically connect bond pads 521 shown in FIG. 9.

Step 608 is optional. If included, in step 608, method 600 places reflowable conductive elements in the trench at locations between each pair of bond pads adjacent thereto. In an example of step 608, a reflowable conductive element 915 is placed between bond pads 521 in scribe-line trench 731, as shown in FIG. 9. Reflowable conductive element 915 touches sidewall surfaces 902, and is for example formed of one or more of solder (e.g., a solder ball) and conductive paste. In one embodiment, step 608 is performed using techniques similar to those disclosed in U.S. Patent Application Publication No. 2014/0326856.

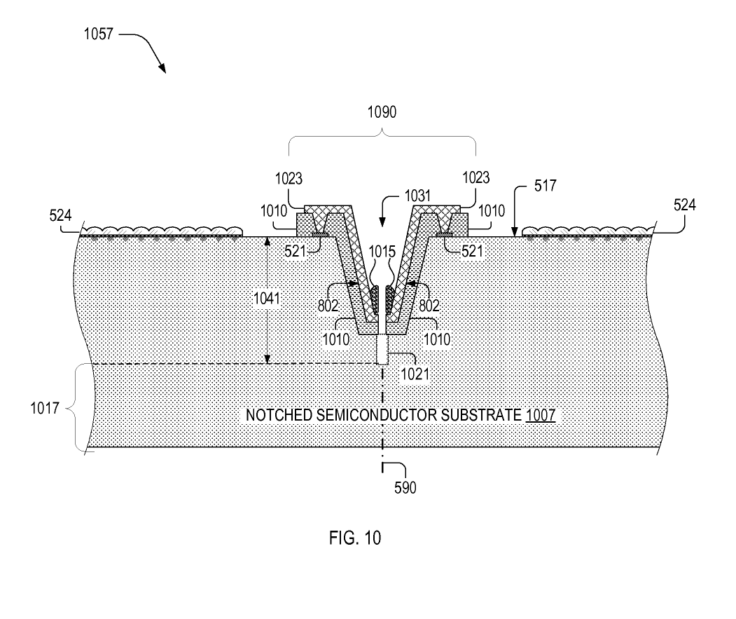

In step 610, method 600 increases the trench depth by removing a portion of image sensor wafer at the bottom thereof. Step 610 yields a pre-cut image sensor wafer that includes a notched semiconductor wafer having a notched region. In an example of step 610, the depth of trench 731 is increased by removing a portion of image sensor wafer 707 in region 921 (FIG. 9), resulting in a pre-cut image sensor wafer 1057 that includes a notched semiconductor wafer 1007 and a trench 1031, shown in FIG. 10. Region 921 is centered along one scribe line 590. Notched semiconductor wafer 1007 is semiconductor substrate 707 with the material within region 921 removed. Trench 1031 has a trench depth 1041 that exceeds trench depth 741 of trench 731.

In an embodiment of step 610, notched semiconductor wafer 1007 is formed by removing parts of reflowable conductive element 915, RDL 923 and isolation layer 810 along scribe line 590, which yields isolation layers 1010, sensor-edge conductors 1023, and reflowable conductive elements 1015 from isolation layer 810, RDL 923, and reflowable conductive element 915, respectively. Isolation layers 1010, sensor-edge conductors 1023, reflowable conductive elements 1015, and one notch region 1021 comprise a connection channel 1090. Notched semiconductor wafer 1007 includes a wafer region 1017 below notch region 1021.

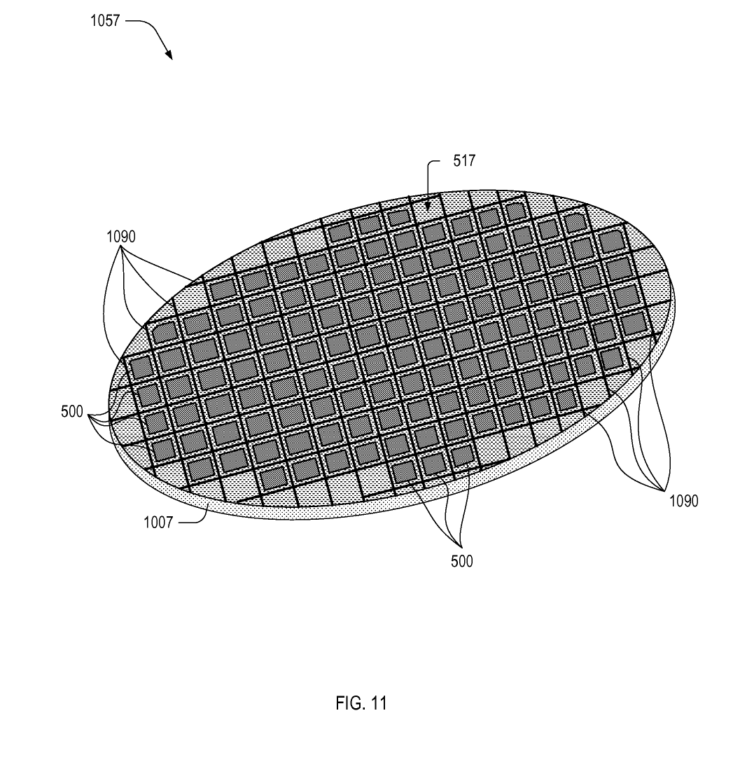

FIG. 11 is a perspective view of pre-cut image sensor wafer 1057 of FIG. 10. One connection channel 1090 is between each row and column of CMOS image sensors 500.

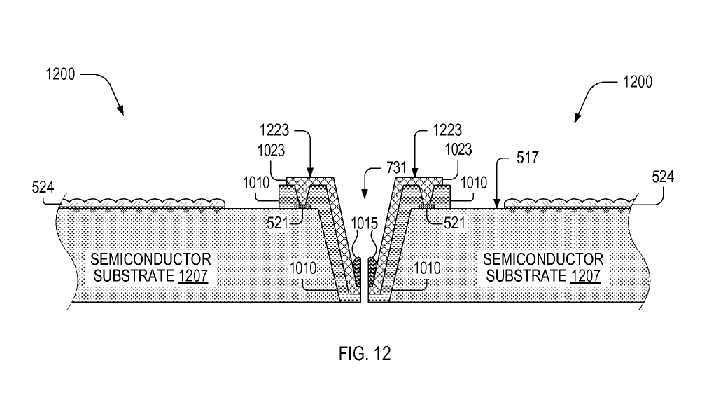

In step 612, method 600 singulates the pre-cut image sensor wafer to form a plurality of space-efficient PCB-mountable image sensors each with a sensor-edge conductor. In an example of step 612, pre-cut image sensor wafer 1057 is singulated by thinning notched semiconductor wafer 1007 to remove wafer region 1017 and expose notched region 1021, which results in space-efficient PCB-mountable image sensors 1200, FIG. 12. Thinning notched semiconductor wafer 1007 may be achieved by a backgrinding process, for example. Each sensor-edge conductor 1023 has a top surface 1223. During step 612, pre-cut image sensor wafer 1057 may be held by a vacuum chuck attached to a disc of tape or a glass disc removably attached to top surfaces 1223.

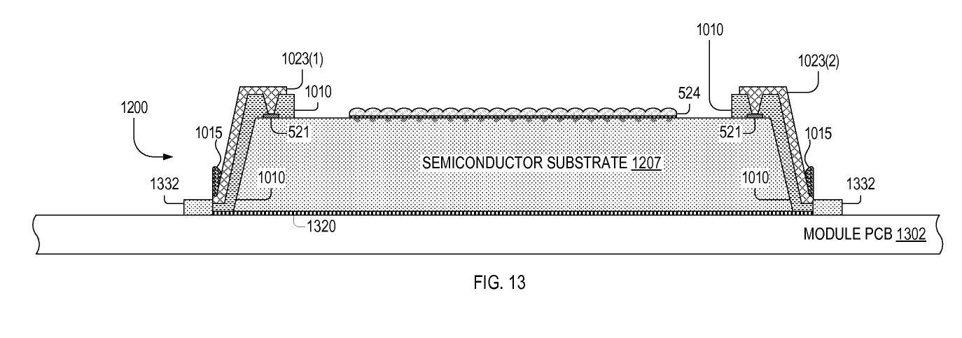

Step 614 is optional. If included, step 614 bonds one space-efficient PCB-mountable image sensor to a PCB having a PCB contact pad sufficiently close to one sensor-edge conductor to allow electrical connection therebetween via reflow of the reflowable conductive element on the sensor-edge conductor. In an example of step 614, one space-efficient PCB-mountable image sensor 1200 is bonded, with a bonding element 1320, to a module PCB 1302 having contact pads 1332 sufficiently close to one of sensor-edge conductors 1023 to allow electrical connection therebetween via reflow of the reflowable conductive element 1015 on the sensor-edge conductor 1023, as shown in FIG. 13. Module PCB 1302 and contact pads 1332 are similar to module PCB 302 and contact pad 332, respectively, of FIG. 3. Bonding element 1320 may include one or more of a glue, epoxy, and attach film, and other bonding elements known in the art

Space-efficient PCB-mountable image sensor 1200 is similar to space-efficient PCB-mountable image sensor 300 of FIG. 3. Semiconductor substrate 1207 is similar to semiconductor substrate 307. For comparison of sensor-edge conductors 1023 to sensor-edge conductors 323, sensor-edge conductors 1023 in FIG. 13 are denoted as sensor-edge conductor 1023(1) and sensor-edge conductor 1023(2). Sensor-edge conductors 1023(1) and 1023(2) are directly opposite each other with respect to pixel array 524. Sensor-edge conductors 1023(1) and 1023(2) may correspond to two sensor-edge conductors 323 that are directly opposite each other with respect to pixel array 324, for example, sensor-edge conductors 323(1) and 323(2), or sensor-edge conductors 323(3) and 323(4).

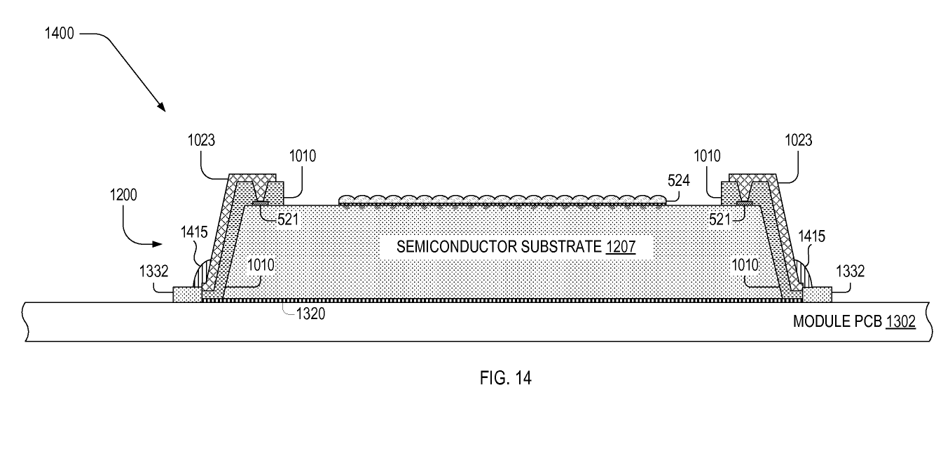

Step 616 is optional. If included, in step 616, method 600 electrically connects the PCB contact pad to its nearest sensor-edge conductor. In an example of step 616, each contact pad 1332 is electrically connected to one sensor-edge conductor 1023 via reflow of reflowable conductive element 1015, as shown in FIG. 14. Each reflowed conductive element 1415 electrically connects one contact pad 1332 to one bond pad 521 via one of sensor-edge conductors 1023. FIG. 14 shows a camera module 1400, which includes space-efficient PCB-mountable image sensor 1200 and module PCB 1302.

In an embodiment of method 600 that does not include step 608, step 616 may include electrically connecting one contact pad 1332 to one sensor-edge conductor 1023 via one or more of soldering, conductive glue, and other means known in the art.

Changes may be made in the above space-efficient PCB-mountable image sensor and associated methods without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall there between.

What is claimed is:

1. A space-efficient PCB-mountable image sensor comprising:
a semiconductor substrate having a top surface and a side surface;
a bond pad on the top surface; and
a conductive layer formed on the side surface and electrically connected to the bond pad.

2. The image sensor of claim 1, the conductive layer being a redistribution layer.

3. The image sensor of claim 1, the conductive layer being electrically connected to a contact pad of a printed circuit board (PCB).

4. The image sensor of claim 3, at least one of a reflowable solder and a conductive paste electrically connecting the conductive layer with the contact pad.

5. The image sensor of claim 1, further comprising an isolation layer between the conductive layer and the semiconductor substrate.

6. The image sensor of claim 1, further comprising a pixel array on the top surface, the bond pad electrically connected thereto, the bond pad between the pixel array and an edge of the semiconductor substrate adjoining the side surface.

7. A method for fabricating a space-efficient PCB-mountable image sensor comprising:
forming a trench next to an image sensor on a first side of an image sensor wafer, the image sensor including a pixel array and a bond pad between the trench and the pixel array;
forming a conductive layer spanning the bond pad and at least part of a sidewall of the trench; and
singulating the image sensor wafer along the trench.

8. The method of claim 7, further comprising, before forming the conductive layer: forming an isolation layer covering the bond pad and at least part of the sidewall, and having an aperture that exposes a bond pad region, such that a portion of the isolation layer is between the sidewall and the conductive layer thereon.

9. The method of claim 7, further comprising:
placing a reflowable conductive element in the trench such that the reflowable conductive element, the conductive layer, and the bond pad are electrically connected.

10. The method of claim 7, the step of singulating comprising:
increasing the trench depth by removing a portion of image sensor wafer at the bottom of the trench; and
thinning the image sensor wafer from a second side of the image sensor wafer to expose the trench, the second side opposing the first side.

11. A camera module comprising:
a printed circuit board (PCB) including a contact pad; and
an image sensor disposed on the PCB and including:
a semiconductor substrate having a top surface and a side surface,
a bond pad on the top surface, and
a conductive layer formed on the side surface and electrically connected between the bond pad and the contact pad.

12. The camera module of claim 11, the conductive layer being a redistribution layer.

13. The camera module of claim 11, further comprising an isolation layer between the conductive layer and the semiconductor substrate.

14. The camera module of claim 11, further comprising a pixel array on the top surface, the bond pad electrically connected thereto, the bond pad between the pixel array and an edge of the semiconductor substrate adjoining the side surface.
